(19) United States
(12) Patent Application Publication
(10) Pub. No.: US 2012/0288109 A1
(43) Pub. Date: Nov. 15, 2012

(54) APPARATUS AND METHOD FOR NOISE GENERATION

(75) Inventors: Deming ZHANG, Beijing (CN); Jinliang DAI, Shenzhen (CN)

(73) Assignee: HUAWEI TECHNOLOGIES CO., LTD., Shenzhen (CN)

(21) Appl. No.: 13/561,784

(22) Filed: Jul. 30, 2012

Related U.S. Application Data
(63) Continuation of application No. 12/748,190, filed on Mar. 26, 2010.
Application No. 12/748,190 is a continuation of application No. PCT/CN2008/072514, filed on Sep. 25, 2008.

(30) Foreign Application Priority Data
Sep. 28, 2007 (CN) 200710151408.9

(51) Int. Cl. H03G 3/00

(52) U.S. Cl. 381/61

(57) ABSTRACT

The disclosure provides a method for noise generation, including: determining an initial value of a reconstructed parameter; determining a random value range based on the initial value of the reconstructed parameter; taking a value in the random value range randomly as a reconstructed noise parameter; and generating noise by using the reconstructed noise parameter. The disclosure also provides an apparatus for noise generation.

### CROSS-REFERENCE TO RELATED APPLICATIONS

This application is a continuation of U.S. patent application Ser. No. 12/748,190, filed on Mar. 26, 2010, which is a continuation of International Application No. PCT/CN2008/072514, filed on Sep. 25, 2008, which claims priority to Chinese Patent Application No. 200710151408.9, filed on Sep. 28, 2007, both of which are hereby incorporated by reference in their entireties.

### FIELD OF THE INVENTION

The present invention relates to the technical field of communications, and more particularly, to an apparatus and method for noise generation.

### BACKGROUND

During voice transmission, speech coding techniques are generally used to compress voice message so that the capacity of a communication system may be improved.

During voice communication, speech only occupies about 40% of a time period, with the remaining time period being occupied by silence or background noise. Generally speaking, people involved in voice communication are concerned about the content of the speech only, while they are not concerned about the time period only having silence or background noise. Therefore, when voice message is being compressed, different methods are used for encoding and transmitting voice message, silence, or background noise so as to further improve the capacity of the communication system. Discontinuous Transmission System/Comfortable Noise Generation (DTX/CNG) is such a technique for further improving the capacity of the communication system.

A frame obtained by encoding the background noise with the DTX/CNG technology is generally referred to as a Silence Insertion Descriptor (SID) frame. An ordinary speech frame contains a spectral parameter, a signal energy gain parameter, as well as parameters associated with a fixed codebook and an adaptive codebook. Upon receiving a speech frame, the decoder may recover the original speech data based on such information. However, an SID frame generally only contains a spectral parameter and a signal energy gain parameter. The decoder may recover the background noise based on the spectral parameter and the signal energy gain parameter. This is due to the fact that users generally do not care what information is contained in the background noise. Accordingly, an SID frame may only deliver a small amount of reference information, i.e. the spectral parameter and the signal energy gain parameter. Based on such reference information, the decoder may recover the background noise so that the user may generally know what environment his/her counterpart is in and the listening quality experienced by the user will not be influenced obviously. During voice transmission, an SID frame is sent at an interval of several frames. A frame in which no coded parameter is sent or no parameter is coded at all may generally be referred to as a NO_DATA frame.

The DTX/CNG technology is widely applied in recent speech coding standards developed by various organizations and institutions.

The DTX/CNG technology is adopted in the speech coding standard—Adaptive Multi-Rate (AMR), developed by the Third Generation Partnership Projects (3GPP). SID frames are sent at fixed intervals, that is, every 8 frames. By using parameters decoded from two consecutively received SID frames, that is, the signal energy gain parameter and the spectral parameter, a linear interpolation is performed to estimate the parameters necessary for noise synthesis, which may be given by:

$${P}_{n + k} = \frac{8 - k}{8} {P}_{sid ( n - 1 )} + \frac{k}{8} {P}_{sid ( n )} ( k = 1 , … , 8 )$$

where Pₙ₊ₖ represents the estimated value of the CNG parameter for the k^{th} frame subsequent to the n^{th} SID frame, P_{sid(n-1)} represents the parameter for the (n−1)^{th} SID frame received by the decoder, and P_{sid(n)} represents the parameter for the n^{th} SID frame received by the decoder. When n=0, P_{sid(-1)} represents the average value of the spectral parameters and signal energy gain parameters for the 8 speech frames in the tail period.

The DTX/CNG technology is also adopted in the speech coding standard—the silence compression scheme defined by the conjugate structure algebra code excited linear prediction speech codec, developed by the International Telecommunication Union (ITU). The encoder may determine adaptively whether to send an SID frame based on changes in the noise parameter. The interval between two consecutive SID frames should be at least 20 ms and have no maximum. The CNG algorithm used at the decoder may be given as follows.

For reconstruction of the signal energy gain parameter:

$${\tilde{G}}_{t} = \{ \begin{matrix}{\tilde{G}}_{sid \_ new} & if the previous frame is a speech frame ; \\ \frac{7}{8} {\tilde{G}}_{t - 1} + \frac{1}{8} {\tilde{G}}_{sid \_ new} & if the previous frame is not speech frame .\end{matrix}$$

For reconstruction of the spectral parameter:

$${LSF}_{t , sub \_ 1} = \{ \begin{matrix}\frac{1}{2} ( {LSF}_{sid \_ last } + {LSF}_{ sid \_ new} ) & \begin{matrix}if the previous frame \\ is a speech frame ;\end{matrix} \\ {LSF}_{sid \_ new} & \begin{matrix}if the previous is not \\ a speech frame\end{matrix}\end{matrix} \\ {LSF}_{t , sub \_ 2} = {LSF}_{sid \_ new}$$

where \tilde{G}_{sid}_{_{—}}_{new} represents the signal energy gain parameter decoded from an SID frame newly received at the decoder, LSF_{sid}_{_{—}}ₗₐₛₜ represents the spectral parameter decoded from an SID frame lastly received at the decoder, and LSF_{sid}_{_{—}}_{new} represents the spectral parameter decoded from an SID frame newly received at the decoder.

In research and applications of the prior arts, the inventors have found the following problems in the prior arts.

For the speech coding standard of 3GPP—the DTX/CNG technology used in AMR, the encoder can only send SID frames at fixed intervals. If the encoder sends SID frames at adaptive intervals, the system cannot work normally.

For the speech coding standard of ITU—the DTX/CNG technology used in the silence compression scheme defined by the conjugate structure algebra code excited linear prediction vocoder, when the current frame is an SID frame, the spectrum parameter of the first sub-frame in the current frame is generated by averaging the decoded spectrum parameter in current frame and the spectrum parameter of previous SID frame, and the decoded spectral parameter is used directly as the spectral parameter for the second sub-frame. For a NO_DATA frame before the arrival of the next SID frame, the decoded spectral parameter for the latest SID frame is used directly for noise reconstruction. When the next SID frame arrives and there is a difference between the decoded spectral parameter and the spectral parameter for the previous SID frame, discontinuity may occur. Furthermore, since the spectral parameter is a variable in constant change and hence there generally is a difference between two consecutive spectral parameters, the spectrum of the reconstructed comfortable noise tends to be discontinuous, which in turn affects the listening quality, especially when there is a big difference between two consecutive spectral parameters.

### SUMMARY

The technical problem to be solved in an embodiment of the invention is to provide a method and apparatus for noise generation, which may accommodate various standard protocols so that the decoder may recover noise comfortable to the users.

To solve the above technical problem, an embodiment of the invention provides a method for noise generation, including:

determining an initial value of a reconstructed parameter;

determining a random value range based on the initial value of the reconstructed parameter;

taking a value in the random value range randomly as a reconstructed noise parameter; and

generating noise by using the reconstructed noise parameter.

An embodiment of the invention provides an apparatus for noise generation, including:

an initial value unit, configured to determine an initial value of a reconstructed parameter;

a range unit, configured to determine a random value range based on the initial value of the reconstructed parameter;

a reconstruction unit, configured to take a value in the random value range randomly as a reconstructed noise parameter; and

a synthesizing unit, configured to generate noise by using the reconstructed noise parameter.

From the above technical solution, it can be seen that there is no limit to the protocol standard used at the encoder in the embodiments of the invention. The technical solution of the invention is operable whether the encoder transmits SID frames at fixed intervals or transmits SID frames at adaptive intervals. Moreover, upon receiving a new SID frame subsequent to the receiving of the first SID frame, the reconstructed noise parameter for a frame previous to the newly received SID frame will be taken as the initial value of the reconstructed parameter. With reference to the initial value of the reconstructed parameter and the noise parameter for the newly received SID frame, a random value range is determined. A value is taken randomly in the range as the noise parameter. Thus, the transition of the generated noise is more natural and a better listening experience is brought to the user.

### BRIEF DESCRIPTION OF THE DRAWINGS

FIG. 1 is a flow chart showing a method for noise generation according to one embodiment of the invention;

FIG. 2 is a flow chart showing a method for noise generation according to another embodiment of the invention;

FIG. 3 is a flow chart showing a method for noise generation according to yet another embodiment of the invention;

FIG. 4 is a flow chart showing a method for noise generation according to yet another embodiment of the invention; and

FIG. 5 is a block diagram showing the configuration of an apparatus for noise generation according to one embodiment of the invention.

### DETAILED DESCRIPTION

The embodiments of the invention provide an apparatus and a method for noise generation, which may accommodate various standard protocols so that the decoder may recover noise comfortable to the users.

In a method for noise generation according to an embodiment of the invention, the decoder may use the noise parameters of a small number of SID frames to reconstruct a noise parameter having a random change and a smooth curve. In this manner, it may facilitate recovery of noise comfortable to the users.

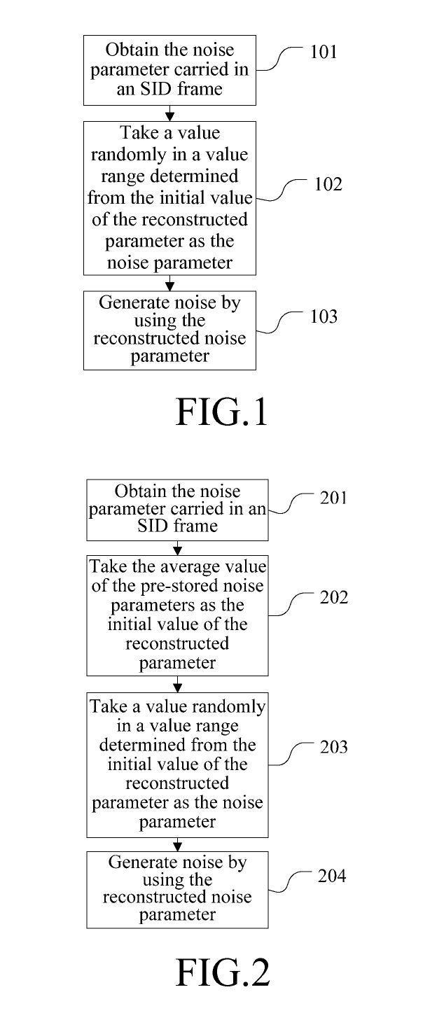

The flow of the method for noise generation according to embodiment One of the invention is shown in FIG. 1.

In step 101, the noise parameter carried in an SID frame is obtained.

After voice communication is started, the decoder may decode information of a frame from the received data packets. Then, a determination is made regarding the format of the frame. If the frame is a speech frame, a speech frame processing flow is started. If the frame is a non-speech frame, such as an SID frame or NO_DATA frame, the flow of the method for noise generation as provided in this embodiment is started.

When a non-speech frame is processed, the procedure directly proceeds to step 102 because the NO_DATA frame contains no speech data. Upon receiving an SID frame, the noise parameter carried in the SID frame is obtained, that is, the signal energy gain parameter and the spectral parameter.

In step 102, based on the obtained noise parameter, continuous noise parameters changing randomly with the predicted direction and having a smooth curve may be reconstructed, the continuous noise parameters including the signal energy gain parameter and the spectral parameter.

The current frame, that is, the frame whose noise parameters are to be reconstructed currently, may be a non-speech frame, including SID frame and NO_DATA frame.

To prevent the reconstructed noise parameter from departing too far away from the actual value, a center value is determined first for the changing curve of the reconstructed noise parameter so that the value of the reconstructed noise parameter floats around the center value. This center value may be referred to as a floating center Cₖ. Meanwhile, the floating range has to be determined so that the value of the reconstructed noise parameter floats in the range having Cₖ as its center. This floating range may be referred to as a floating radius Δ.

There are various methods for obtaining the floating radius Δ. Two of the methods are provided in this embodiment. According to one method, the floating radius may be obtained according to the noise parameter increment dP, the predicted interval length length, and the time interval k between the current frame and the newly received SID frame. According another method, the floating radius may be obtained according to the noise parameter increment dP and the predicted interval length length.

When the floating radius Δ is obtained according to the first method, the floating radius Δ for the noise parameter of the current frame may be obtained according to the following equation:

$$Δ = \frac{dP}{2 ( \vert k - length \vert + 1 )}$$

where length is the predicted length of the interval between the newly received SID frame and the next SID frame. In other words, it is assumed that the next SID frame may be received after the time period length.

When the current frame is the first SID frame received by the decoder subsequent to the speech frame, the noise parameter increment dP may be obtained by using the noise parameter P_{sid} for the newly received SID frame or the energy gain parameter and the spectral parameter of the several previous speech frames stored in the buffer.

When the decoder receives the first non-speech frame subsequent to the speech frame, two methods for obtaining the noise parameter increment are provided according to some embodiments.

Method 1:

The energy gain parameters and the spectral parameters of a few previous speech frames stored in the buffer may be used for estimating the previous average energy gain parameter and spectral parameter as the initial value of the reconstructed parameter P_{ref}. The difference between the newly received noise parameter P_{sid} and the initial value of the reconstructed parameter P_{ref} may be taken as the noise parameter increment dP. In this case, the noise parameter increment dP may be obtained according to the following equation:

dP=P_{sid}−P_{ref}.

Estimation of the initial value of the reconstructed parameter P_{ref} may vary. The average value of the energy gain parameters and spectral parameters of several previous frames may be taken as the initial value of the reconstructed parameter P_{ref}. Alternatively, the weighted average value of the energy gain parameters and spectral parameters of several previous frames may be taken as the initial value of the reconstructed parameter P_{ref}.

Method 2:

By directly using the energy gain parameter and spectral parameter carried in a newly received SID frame, the noise between the newly received SID frame and the next SID frame may be reconstructed. Upon receiving an SID frame next to the newly received SID frame, reconstruction of the noise parameter starts. The energy gain parameter and spectral parameter carried in the first SID frame subsequent to the speech frame may be taken as the initial value of the reconstructed parameter P_{ref}, and the difference between the newly received noise parameter P_{sid} and the initial value of the reconstructed parameter P_{ref} may be taken as the noise parameter increment dP. Now, the noise parameter increment dP may be obtained according to the following equation:

dP=P_{sid}−P_{ref}.

If the current frame is an SID frame received after the first SID frame or a NO_DATA frame subsequent to the first SID frame, two methods for obtaining the noise parameter increment are provided according to some embodiments.

Method 1:

The reconstructed noise parameter Pₖ₋₁ of a frame previous to the newly received SID frame is taken as the initial value of the reconstructed parameter P_{ref}, and the difference between the noise parameter P_{sid} of the newly received SID frame and the initial value of the reconstructed parameter P_{ref} is taken as the noise parameter increment dP. Now, the noise parameter increment dP may be obtained according to the following equation:

dP=P_{sid}−P_{ref}.

Method 2:

The difference between the noise parameter carried in the newly received SID frame and the noise parameter carried in the previous SID frame is taken as the noise parameter increment dP. In an example where the newly received SID frame is the n^{th} frame, the noise parameter increment dP may be obtained according to the following equation:

dP=P_{sid(n)}−P_{sid(n-1)}.

Before receiving the next SID frame, when the noise parameter is to be reconstructed for a NO_DATA frame between two SID frames, the noise parameter increment dP for the newly received SID frame may be used for determining the floating radius Δ for the NO_DATA frame. Also, the noise parameter increment dP is updated whenever noise is reconstructed for a new NO_DATA frame. Some embodiment provides two methods for updating the noise parameter increment dP.

Method 1:

The difference between the noise parameter P_{sid} of the newly received SID frame and the initial value of the reconstructed parameter P_{ref} is taken as the noise parameter increment dP. When the noise parameter is reconstructed for a NO_DATA frame, the reconstructed noise parameter Pₖ₋₁ for the previous frame is used for updating the initial value of the reconstructed parameter P_{ref}. The noise parameter increment dP obtained by using the initial value of the reconstructed parameter P_{ref} will be updated accordingly.

Method 2:

The difference between the noise parameter of the newly received SID frame and the noise parameter carried in the previous SID frame is taken as d₀, the reconstructed noise parameter of a frame previous to the newly received SID frame is taken as P₀, the current frame is the k^{th} frame from the newly received SID frame, and the noise parameter increment for the current frame is dₖ. The noise parameter increment dₖ of the current frame may be obtained by subtracting the difference between the initial value of the reconstructed parameter P_{ref} and P₀ from d₀ so that dₖ=dP. Now, dₖ may be obtained according to the following equation:

dₖ=d₀−(P_{ref}−P₀).

When reconstructing the noise parameter for the NO_DATA frame, the initial value of the reconstructed parameter P_{ref} may be updated by using the reconstructed noise parameter Pₖ₋₁ of the previous frame. Then, the noise parameter increment dₖ obtained by using the initial value of the reconstructed parameter P_{ref} will be updated accordingly.

The predicted direction of the changing curve is also the value direction of the floating radius Δ. The value direction of the floating radius Δ is under the influence of the noise parameter increment dP. When the noise parameter increment dP is “+”, the value of Δ is “+”. When the noise parameter increment dP is “−”, the value of Δ is “−”.

When the current frame is an SID frame, k is “0”,

$$2 ( \vert k - length \vert + 1 ) = 2 ( length + 1 )$$

$$Δ = \frac{dP}{2 ( length + 1 )}$$

As the duration of a NO_DATA segment consisting of NO_DATA frames becomes longer, the value k becomes greater slowly. When the noise parameter increment dP keeps unchanged, the value of 2(|k−length|+1) will become smaller slowly, and the value of k becomes greater slowly.

When k=length, that is, the current frame is the length^{th} frame after the newly received SID frame,

$$2 ( \vert k - length \vert + 1 ) = 2$$

$$Δ = \frac{dP}{2}$$

If no new SID frame is received after the frame, the value of k continues to increase. When the noise parameter increment dP keeps unchanged, the value of 2(|k−length|+1) will become greater slowly, and the value Δ will become smaller slowly.

When the noise parameter is reconstructed for a NO_DATA frame between two SID frames and the noise parameter increment dP keeps unchanged, the value of Δ is a value which has an initial value equal to

$$\frac{dP}{2 ( length + 1 )}$$

and an maximum equal to

$$\frac{dP}{2} ,$$

and then fades slowly. If the noise parameter increment dP changes accordingly, the change in the value of Δ will be influenced accordingly.

When obtaining the floating radius Δ with the second method, the floating radius Δ for the noise parameter of the current frame may be obtained according to the following equation:

$$Δ = \frac{dP}{2 * length}$$

The method for obtaining the noise parameter increment dP and the predicted interval length length substantially similar to the above first method for obtaining the floating radius Δ.

In such case, the value direction of the floating radius Δ is still influenced by the noise parameter increment dP. When the noise parameter increment dP is “+”, the value of Δ is “+”; when the noise parameter increment dP is “−”, the value of Δ is “−”.

The floating center Cₖ for the noise parameter of the current frame may be obtained via the initial value of the reconstructed parameter P_{ref} and the floating radius Δ for the noise parameter of the current frame. The floating center Cₖ may be obtained according to the following equation:

Cₖ=P_{ref}+2Δ

Here, the initial value of the reconstructed parameter P_{ref} will be updated each time the noise parameter is reconstructed. It is assumed that the current noise parameter is Pₖ and P_{ref} is updated with Pₖ₋₁. The floating center Cₖ may then be written as:

Cₖ═Pₖ₋₁+2Δ

With Cₖ as the center, a method may be used for taking a random value within the interval [Cₖ−|Δ|, Cₖ+|Δ|], and then the noise parameter Pₖ of the current frame may be reconstructed. The noise parameter Pₖ may be written as:

Pₖ=rand(Cₖ−|Δ|,Cₖ+|Δ|)

When the current frame is an SID frame and the Δ value is “+”, Cₖ is greater than the noise parameter Pₖ₋₁ of the previous frame, and the minimum of [Cₖ−|Δ|, Cₖ+|Δ|] is:

Cₖ−|Δ|=Pₖ₋₁+Δ

The minimum of [Cₖ−|Δ|, Cₖ+|Δ|] is higher than Pₖ₋₁ by Δ. When Δ is obtained with the first method, the initial value of the value Δ is equal to

$$\frac{dP}{2 ( length + 1 )} ,$$

which is

$$\frac{1}{2 ( length + 1 )}$$

of the noise parameter increment dP. This is very small relative to the noise parameter increment dP. Therefore, the minimum of [Cₖ−|Δ|, Cₖ+|Δ|] is a value slightly higher than Pₖ₋₁.

When Δ is obtained with the second method,

$$Δ = \frac{{P}_{sid} - {P}_{k - 1}}{2 * length} .$$

The value of Δ is

$$\frac{1}{2 * length}$$

of the noise parameter increment, which is very small relative to the noise parameter increment dP. Therefore, the minimum of [Cₖ−|Δ|, Cₖ+|Δ|] is also a value slightly higher than Pₖ₋₁.

The maximum of [Cₖ−|Δ|, Cₖ+|Δ|] is:

Cₖ+|Δ|=Pₖ₋₁+3Δ

The maximum of [Cₖ−|Δ|, Cₖ+|Δ|] is higher than Pₖ₋₁ by 3 Δ. When Δ is obtained with the first method, for example, when the value of length “2”, the value of 3 Δ is ½ of the noise parameter increment dP, which is still smaller than the noise parameter increment dP. In other words, the maximum of [Cₖ−|Δ|, Cₖ+|Δ|] is lower than the sum of Pₖ₋₁ and the noise parameter increment dP.

When Δ is obtained with the second method, for example, when the value of length is “2”, the value of 3Δ is ¾ of the difference between P_{sid} and Pₖ₋₁, which is still smaller than the noise parameter increment dP. In other words, the maximum of [Cₖ−|Δ|, Cₖ+|Δ|] is lower than the sum of Pₖ₋₁ and the noise parameter increment dP. Moreover, the second method generally is applied to cases where SID frames are sent at fixed intervals. In these cases, length is typically much greater than “2”, and hence the value of 3 Δ is even smaller.

Similarly, if the current frame is an SID frame and the value Δ is “−”, the minimum of [Cₖ−|Δ|, Cₖ+|Δ|] will be higher than the noise parameter P_{sid} of the newly received SID frame, and the maximum will be slightly lower than the noise parameter Pₖ₋₁ of the previous frame.

Therefore, when the current frame is an SID frame, the noise parameter Pₖ taking a random value within the interval [Cₖ−|Δ|, Cₖ+|Δ|] will be a parameter having a slight change compared with the noise parameter Pₖ₋₁ of the previous frame. Such a change is a mild change influenced by the noise parameter P_{sid} of the newly received SID frame. Even if the noise parameter P_{sid} of the newly received SID frame is distinctly different from the noise parameter Pₖ₋₁ of the previous frame, Pₖ is a value having a smooth transition. The noise generated from Pₖ will also change slightly and thus may bring better user experience.

When the current frame is a NO_DATA frame, the initial value of the reconstructed parameter P_{ref} is the reconstructed noise parameter Pₖ₋₁ of the previous frame. The floating center Cₖ is influenced by the initial value of the reconstructed parameter P_{ref}, and will change smoothly towards the value direction of the floating radius Δ. The noise parameter Pₖ having a random value within the interval [Cₖ−|Δ|, Cₖ+|Δ|] may be a parameter changed slightly with respect to the noise parameter Pₖ₋₁ of the previous frame. The continuous noise parameter Pₖ reconstructed between two SID frames will be a value having a smooth transition. The noise generated from Pₖ will also change slightly and thus may bring better user experience.

Further, the floating radius Δ between two SID frames might change under the influence of the value of k or the value of dP. The range of the random value will also change accordingly. The continuous noise parameter Pₖ reconstructed between two SID frames will be a curve changing more randomly. The noise generated from Pₖ will also change more differently and thus may bring better user experience.

In some cases, when the current frame is a NO_DATA frame, it is likely that the initial value of the reconstructed parameter P_{ref} will not be updated before the arrival of the next SID frame. The change of the range of the random value depends on the change of the floating radius Δ.

In this embodiment, the initial value of the reconstructed parameter P_{ref} includes the initial value of the reconstructed signal energy gain parameter and the initial value of the reconstructed spectral parameter.

In step 103, noise is generated by using the reconstructed noise parameter.

The decoder uses a random sequence generator to synthesize an excitation signal. When noise is reconstructed, the excitation signal is equivalent to what an SID frame lacks as compared to an ordinary speech frame, for example, parameters associated with the fixed codebook and the adaptive codebook, etc. Based on the commonness of noise, the decoder uses a random sequence generator to synthesize an excitation signal for noise reconstruction.

There are two methods for noise generation by using the excitation signal and the reconstructed noise parameter.

In the first method, the decoder converts the spectral parameter in the reconstructed noise parameter to synthesis filter coefficients, performs a synthesis filtering on the excitation signal, and obtains a noise signal. Then, a time-domain shaping is performed on the synthesized noise signal by using the energy gain parameter in the reconstructed noise parameter. A post processing is performed, and the final reconstructed noise may be output.

In the second method, the decoder uses the energy gain parameter in the reconstructed noise parameter and the random sequence generator to synthesize an excitation signal. Then, the spectral parameter in the reconstructed noise parameter is converted to synthesis filter coefficients. Synthesis filtering is applied to the excitation signal to obtain a noise signal.

In this embodiment, there is no limit to the protocol standards used in the encoder. The technical solution of the invention is operable whether the encoder transmits SID frames at fixed intervals or transmits SID frames at adaptive intervals. Moreover, each time a new SID frame is received, noise parameter reconstruction will refer to the reconstructed noise parameter of the previous frame and the newly received noise parameter. Thus, the transition of the generated noise is natural and a better listening experience may be brought to the user. Furthermore, the influence of the actual noise parameter is referred to so that the user may discern the approximate speech environment. Further, when a NO_DATA frame is processed, a noise parameter slightly changed relative to the previous frame is reconstructed for the NO_DATA frame based on the distance between the NO_DATA frame and the latest SID frame, the changing direction of the noise parameter of the latest SID frame, and the difference between the noise parameter of the latest SID frame and the initial value of the reconstructed parameter. In this way, the changing curve of the reconstructed noise parameter is smooth. Accordingly, the transition of the generated noise is also natural between frames, and a better listening experience may be brought to the user.

In the method for noise generation according to embodiment Two of the invention, the encoder sends SID frames at adaptive intervals. The flow is shown in FIG. 2.

In step 201, an SID frame is received and the noise parameter carried in the SID frame is obtained.

After voice communication starts, the decoder may decode information of a frame from the received data packets. Then, a determination is made regarding the format of the frame. If the frame is a speech frame, the speech frame processing flow is started. If the frame is a non-speech frame, such as an SID frame or a NO_DATA frame, the flow of the method for noise generation as provided in this embodiment is started.

When a non-speech frame is processed, the procedure directly proceeds to step 202 because the NO_DATA frame contains no speech data. Upon receiving an SID frame, the noise parameter carried in the SID frame may be obtained, that is, the signal energy gain parameter G_{sid} and the spectral parameter lsf_{sid}.

In step 202, the initial value of the reconstructed parameter is obtained.

When the decoder detects that the frame type is changing from a speech frame to a non-speech frame, that is, when receiving the first SID frame, the energy gain parameters and spectral parameters of the previous Nₚ frames stored in the buffer may be used for calculating the average energy gain parameter G_{ref} and spectral parameter lsf_{ref} as the initial value of the reconstructed parameter. Here, the value of Nₚ is an integer more than 0, for example, Nₚ=5. The previous frames may be speech frames or SID frames. Reconstruction of the initial value of the energy gain parameter G_{ref} and reconstruction of the initial value of the spectral parameter lsf_{ref} may be obtained according to the following equation:

$${lsf}_{ref} = \frac{1}{{N}_{p}} {\sum }_{i = 1}^{{N}_{p}} {lsf}_{i}$$

$${G}_{ref} = \frac{1}{{N}_{p}} {\sum }_{i = 1}^{{N}_{p}} {G}_{i}$$

If the received SID frame is not the first SID frame, the energy gain parameter and spectral parameter reconstructed for the frame previous to the SID frame may be used as the initial value of the reconstructed parameter.

When the noise parameter is reconstructed for the NO_DATA frame according to one embodiment, the initial value of the reconstructed parameter may be updated by using the energy gain parameter and spectral parameter reconstructed for the previous frame. Alternatively, the initial value of the reconstructed parameter may not be updated before the arrival of the next SID frame.

In step 203, the noise parameter is reconstructed.

When a transition occurs from the speech segment to the noise segment, in other words, when the first SID frame subsequent to the speech frame is received, the initial value of length is set to Nₚ. When another SID frame is received afterwards, the length of the interval between the latest SID frame and its previous SID frame is taken. To guarantee the efficiency of DTX, the transmission interval for SID frames is generally limited, that is, length must be greater than or equal to a natural number. For example, it is defined in the protocol G.729B release that length must be greater than or equal to 2.

The energy gain parameter decoded from the latest SID frame is G_{sid} and the spectral parameter is lsf_{sid}. For the k^{th} frame subsequent to the SID frame, the noise parameter increment d_{k,G} of its energy gain parameter may be obtained according to the following equation:

d_{k,G}=G_{sid}−G_{ref}

The floating radius Δ_{G} of its energy gain parameter may be obtained according to the following equation:

$${Δ}_{G} = \frac{{d}_{k , G}}{2 ( \vert k - length \vert + 1 )}$$

The noise parameter increment d_{k,lsf} of its spectral parameter may be written as:

d_{k,lsf}=lsf_{sid}−lsf_{ref}

The floating radius Δ_{lsf}ⁱ of its spectral parameter may be written as:

$${Δ}_{lsf}^{i} = \frac{{d}_{k , lsf}}{2 ( \vert k - length \vert + 1 )} \qquad i = 1 , 2 , ⋯ , M$$

where M is the order of linear prediction of the spectral parameter.

Then, the floating center C_{G,k} of the reconstructed energy gain parameter in the reconstructed noise parameter of the current frame may be obtained according to the following equation:

C_{G,k}=G_{ref}+2Δ_{G}

The floating center C_{lsf,k}ⁱ of the reconstructed spectral parameter in the reconstructed noise parameter of the current frame may be obtained according to the following equation:

C_{lsf,k}ⁱ=lsf_{ref}+2Δ_{lsf}ⁱ

The reconstructed energy gain parameter Gₖ in the reconstructed noise parameter of the current frame may be obtained according to the following equation:

Gₖ=rand(C_{G,k}−|Δ_{G}|,C_{G,k}+|Δ_{G}|)

The reconstructed spectral parameter lsfₖⁱ in the reconstructed noise parameter of the current frame may be obtained according to the following equation:

lsfₖⁱ=rand(C_{lsf,k}ⁱ−|Δ_{lsf}ⁱ,C_{lsf,k}ⁱ+|Δ_{lsf}ⁱ|)

where function rand(a,b) represents taking a random value uniformly distributed in the interval [a, b].

When a new SID frame is received, the associated variables may be updated as follows:

length=k−1;

G_{ref}=Gₖ₋₁;

lsf_{ref}=lsfₖ₋₁^{l}; and

finally k=1.

When a NO_DATA frame is received, the initial value of the reconstructed parameter is updated so that:

G_{ref}=Gₖ; and

lsf_{ref}=lsfₖ.

The initial value of the reconstructed parameter is updated, and then k=k+1.

The reconstruction of the noise parameter of the frame continues until a new SID frame is received.

In step 204, the reconstructed noise parameter is employed to generate noise.

A white noise excitation signal e(n) is generated by using a random sequence.

The reconstructed spectral parameter lsfₖ is employed to form a synthesis filter aₖ(z).

The synthesis filter is used to synthesis filter the generated excitation signal:

yₖ(n)=e(n)*aₖ(n)

Then, the reconstruct energy gain parameter Gₖ is used to perform a time-domain shaping on the synthesized noise yₖ(n).

$$y ( n ) = {y}_{k} ( n ) \times \frac{{G}_{k}}{\sqrt{{\sum }_{i = 0}^{N - 1} {y}_{k}^{2} ( n )}}$$

where N is the length of frame in which comfortable noise may be recovered at the decoder.

In this embodiment, step 204 uses the method for noise generation with the reconstructed noise parameter, that is, the above mentioned first method for noise generation with the excitation signal and the reconstructed noise parameter.

In this embodiment, there is no limit to the protocol standards used in the encoder. The technical solution of the invention is operable whether the encoder transmits SID frames at fixed intervals or transmits SID frames at adaptive intervals. Moreover, when a transition occurs from the speech segment to the noise segment, the noise parameter is reconstructed by taking the average energy gain parameter and spectral parameter of the latest speech segment as the initial value and referring to the newly received noise parameter. Thus, when a change occurs from the speech segment to the noise segment, the transition of the generated noise and the speech segment may be natural and the user may have a better listening experience. Meanwhile, due to reference to the influence of the actual noise parameter, the user may discern the approximate speech environment. Every time a new SID frame is received, the noise parameter is reconstructed by taking the reconstructed noise parameter of its previous frame as the initial value and referring to the newly received noise parameter. The transition of the generated noise is thus natural, and the user may have a better listening experience. Meanwhile, also due to reference to the influence of the actual noise parameter, the user may discern the approximate speech environment. Further, when a NO_DATA frame is processed, the noise parameter having a change slightly different from the previous frame is reconstructed for the NO_DATA frame based on the distance between the NO_DATA frame and the latest SID frame, the changing direction of the noise parameter of the latest SID frame, and the difference between the noise parameter of the latest SID frame and the initial value of the reconstructed parameter, so that the changing curve of the reconstructed noise parameter may be smooth. Therefore, the transition of the generated noise is natural between frames and a better listening experience may be brought to the user.

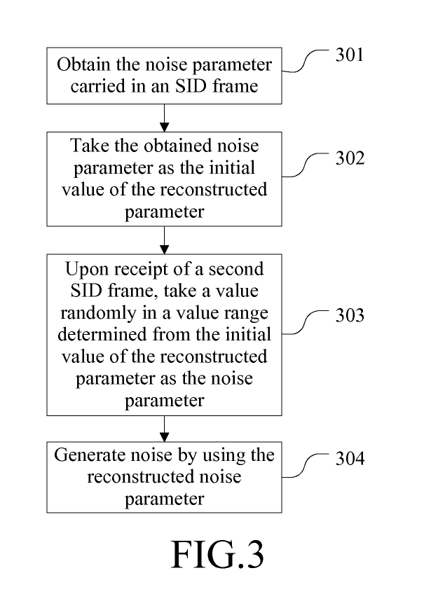

With the method for noise generation as provided in embodiment Three of the invention, the encoder sends SID frames at fixed intervals. The flow chart is shown in FIG. 3.

In step 301, an SID frame is received and the noise parameter carried in the SID frame is obtained.

After voice communication starts, the decoder may decode information about a frame from the received data packets. Then, a determination is made regarding the format of the frame. If the frame is a speech frame, the speech frame processing flow is started. If the frame is a non-speech frame, such as an SID frame or NO_DATA frame, the flow of the method for noise generation as provided in this embodiment is started.

When a non-speech frame is processed, the procedure directly proceeds to step 302 because the NO_DATA frame contains no speech data. Upon receiving an SID frame, the noise parameter carried in the SID frame may be obtained, that is, the signal energy gain parameter G_{sid} and the spectral parameter lsf_{sid}.

In step 302, the initial value of the reconstructed parameter is obtained.

The encoder sends SID frames at fixed SID frame intervals. It is assumed here that the SID frame interval is LENGTH, with the value of LENGTH being a natural number greater than 0.

When the decoder detects that the frame type is changing from a speech frame to a non-speech frame, that is, when receiving the first SID frame, the noise parameter of the received SID frame may be used as the reconstructed noise parameter of the future LENGTH frames, and used as the initial value of the reconstructed noise energy gain parameter G_{ref} and spectral parameter lsf_{ref}. Reconstruction of the initial value of the energy gain parameter G_{ref} and reconstruction of the initial value of the spectral parameter lsf_{ref} as follows:

lsf_{ref}=lsf_{sid(1)}

G_{ref}=G_{sid(1)}

In step 303, the noise parameter is reconstructed.

The reconstruction of the noise parameter starts from the receiving of the second SID frame. The energy gain parameter decoded from the latest SID frame is G_{sid} and the spectral parameter is lsf_{sid}. For the k^{th} frame subsequent to the SID frame, the noise parameter increment d_{k,G} of its energy gain parameter may be obtained according to the following equation:

d_{k,G}=G_{sid}−G_{ref}

The floating radius Δ_{G} of its energy gain parameter may be obtained according to the following equation:

$${Δ}_{G} = \frac{{d}_{k , G}}{2 * LENGTH}$$

The noise parameter increment d_{k,lsf} of its spectral parameter may be written as:

d_{k,lsf}=lsf_{sid}−lsf_{ref}

The floating radius Δ_{lsf}ⁱ of its spectral parameter may be written as:

$${Δ}_{lsf}^{i} = \frac{{d}_{k , lsf}}{2 * LENGTH} \qquad i = 1 , 2 , ⋯ , M$$

where M is the order of linear prediction.

The floating center C_{G,k} of the reconstructed energy gain parameter in the reconstructed noise parameter of the current frame may be obtained according to the following equation:

C_{G,k}=G_{ref}+2Δ_{G}

The floating center C_{lsf,k}ⁱ of the reconstructed spectral parameter in the reconstructed noise parameter of the current frame may be obtained according to the following equation:

C_{lsf,k}ⁱ=lsf_{ref}+2Δ_{lsf}ⁱ

The reconstructed energy gain parameter Gₖ in the reconstructed noise parameter of the current frame may be obtained according to the following equation:

Gₖ=rand(C_{G,k}−|Δ_{G}|,C_{G,k}+|Δ_{G}|)

The reconstructed spectral parameter lsfₖⁱ in the reconstructed noise parameter of the current frame may be obtained according to the following equation:

lsfₖⁱ=rand(C_{lsf,k}ⁱ−|Δ_{lsf}ⁱ,C_{lsf,k}ⁱ+|Δ_{lsf}ⁱ|)

where function rand(a,b) is a random value uniformly distributed with the interval [a, b].

Upon receiving a new SID frame, the associated variables may be updated as follows.

length=k−1;

G_{ref}=Gₖ₋₁.

lsf_{ref}=lsfₖ₋₁; and

finally k−1.

Upon receiving a NO_DATA frame, the initial value of the reconstructed parameter may be updated so that:

G_{ref}=Gₖ; and

lsf_{ref}=lsfₖ.

The initial value of the reconstructed parameter may be updated, and then k=k+1.

The reconstruction of the noise parameter of the frame continues until receiving a new SID frame.

In step 304, noise is generated by using the reconstructed noise parameter.

A white noise excitation signal e(n) is synthesized by using a random sequence generator and the reconstruct energy gain parameter Gₖ.

The reconstructed spectral parameter lsfₖ is used for forming a synthesis filter aₖ(z).

The generated excitation signal may be synthesis filtered with a synthesis filter.

yₖ(n)=e(n)*aₖ(n)

After a further post filtering, comfortable noise may be recovered at the decoder.

In this embodiment, step 304 uses the method for noise generation with the reconstructed noise parameter, that is, the above mentioned second method for noise generation with the excitation signal and the reconstructed noise parameter.

In this embodiment, there is no limit to the protocol standards used in the encoder. No matter whether the encoder transmits SID frames at fixed intervals or transmits SID frames at adaptive intervals, smooth noise parameters may be reconstructed, including the energy gain parameter, the spectral parameter, etc. Then, natural comfortable noise may be generated.

When a change occurs from the speech segment to the noise segment, the noise parameter of the newly received SID frame may be used for generating noise between the first SID frame and the next SID frame. Each time a new SID frame is received, the noise parameter is reconstructed and then noise is generated by taking the reconstructed noise parameter of its previous frame as the initial value and referring to the newly received noise parameter. When a change occurs from the speech segment to the noise segment, the transmitted SID frame is very close to the speech segment. Thus, the noise parameter of the newly received SID frame is used directly to generate noise between the first SID frame and the next SID frame. The transition from the speech segment to the noise segment will be natural. The interval between two SID frames is very short. Thus noise has no change in a short time period, and cannot be discerned by the listening experience of an ordinary person. Therefore, the user may have a better listening experience. Each time a new SID frame is received, the noise parameter is reconstructed by taking the reconstructed noise parameter of its previous frame as the initial value and referring to the newly received noise parameter. The transition of the generated noise is natural, and the user may have a better listening experience. Meanwhile, by referring to the influence of the actual noise parameter, the user may discern the approximate speech environment. Further, when a NO_DATA frame is processed, based on the distance between the NO_DATA frame and the latest SID frame, the changing direction of the noise parameter of the latest SID frame, and the difference between the noise parameter of the latest SID frame and the initial value of the reconstructed parameter, the noise parameter is reconstructed for the NO_DATA frame which may have a slight change relative to the previous frame so that the reconstructed noise parameter has a smooth changing curve. Therefore, the transition of the generated noise is more natural between frames, and the user may have a better listening experience.

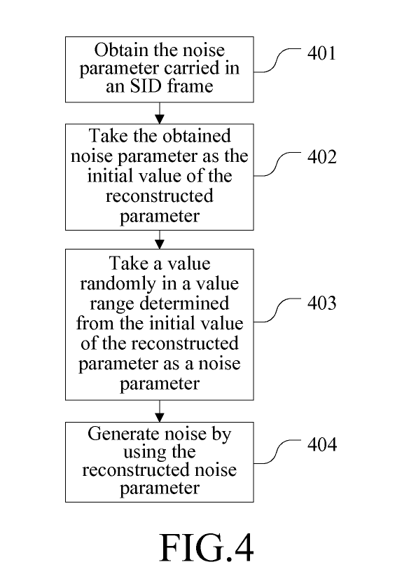

In the method for noise generation as provided in embodiment Four of the invention, the encoder transmits SID frames at adaptive intervals. The flow chart is shown in FIG. 4.

In step 401, an SID frame is received, and the noise parameter carried in the SID frame is obtained.

After voice communication starts, the decoder may decode information about a frame from the received data packets. Then, a determination is made regarding the format of the frame. If the frame is a speech frame, the speech frame processing flow is started. If the frame is a non-speech frame, such as an SID frame or NO_DATA frame, the flow of the method for noise generation as provided in this embodiment is started.

When a non-speech frame is processed, the procedure directly proceeds to step 402 because the NO_DATA frame contains no speech data. Upon receiving an SID frame, the noise parameter carried in the SID frame may be obtained, that is, the signal energy gain parameter G_{sid} and the spectral parameter lsf_{sid}.

In step 402, the initial value of the reconstructed parameter is obtained.

When the decoder detects that the frame type is changing from a speech frame to a non-speech frame, that is, when receiving the first SID frame, it is assumed that the signal energy gain parameter obtained from the frame is G_{sid(1)} and the spectral parameter is lsf_{sid(1)}. Reconstruction of the initial value of the energy gain parameter G_{ref} and reconstruction of the initial value of the spectral parameter lsf_{ref} may be obtained according to the following equation:

G_{ref}=G_{sid(1)}

lsf_{ref}=lsf_{sid(1)}

If the received SID frame is not the first SID frame, the energy gain parameter and spectral parameter reconstructed for the frame previous to the SID frame may be used as the initial value of the reconstructed parameter.

When the noise parameter is reconstructed for the NO_DATA frame in this embodiment, the initial value of the reconstructed parameter may be updated by using the energy gain parameter and spectral parameter reconstructed for the previous frame. Alternatively, the initial value of the reconstructed parameter may not be updated before the arrival of the next SID frame.

In step 403, the noise parameter is reconstructed.

When a change occurs from the speech segment to the noise segment, in other words, when the first SID frame subsequent to the speech frame is received, the initial value of length is set to Nₚ. Afterwards, when another SID frame is received, the length of the interval between the latest SID frame and its previous SID frame is taken. To guarantee the efficiency of DTX, the transmission interval for SID frames generally is limited, that is, length must be more than or equal to a natural number. For example, it is defined in the protocol G.729B release that length must be more than or equal to 2.

The energy gain parameter decoded by the decoder from the latest SID frame is G_{sid(n)} and the spectral parameter is lsf_{sid(n)}, (n=1, 2, . . . ) so that:

d_{0,G}=G_{sid(n)}−G_{sid(n-1)}

d_{0,lsf}=lsf_{sid(n)}−lsf_{sid(n-1)}

For the k^{th} frame subsequent to the n^{th} SID frame, the noise parameter increment d_{k,G} of its energy gain parameter may be written as:

d_{k,G}=d_{0,G}−(G_{ref}−G₀)

where G_{ref} is the initial value of the reconstructed parameter in the energy gain parameter, and G₀ is the energy gain parameter reconstructed for the frame previous to the newly received SID frame.

When the newly received SID frame is the first frame SID frame, G₀ is the weighted average value G_{sid(0)} of the energy gain parameters for the previous Nₚ frames stored in the buffer. G_{sid(0)} may be written as follows:

$${G}_{sid ( 0 )} = {\sum }_{i = 1}^{{N}_{p}} {w}_{i} \times {G}_{i}$$

where wᵢ is the weight value and

$${\sum }_{i = 1}^{{N}_{p}} {w}_{i} = 1.$$

The floating radius Δ_{G} of its energy gain parameter may be written as:

$${Δ}_{G} = \frac{{d}_{k , G}}{2 ( \vert k - length \vert + 1 )}$$

The noise parameter increment d_{k,lsf}ⁱ of its spectral parameter may be written as:

d_{k,lsf}ⁱ=d_{0,lsf}−(lsf_{ref}−lsf₀)

where lsf_{ref} is the initial value of the reconstructed parameter for the spectral parameter, and lsf₀ is the spectral parameter reconstructed for the frame previous to the newly received SID frame.

When the newly received SID frame is the first frame SID frame, lsf₀ is the weighted average value lsf_{sid(0)} of the energy gain parameters for the previous Nₚ frames stored in the buffer. lsf_{sid(0)} may be written as follows:

$${lsf}_{sid ( 0 )} = {lsf}_{0} = {\sum }_{i = 1}^{{N}_{p}} {w}_{i} \times {lsf}_{i}$$

where wᵢ is the weight value and

$${\sum }_{i = 1}^{{N}_{p}} {w}_{i} = 1.$$

The floating radius Δ_{lsf}ⁱ of its spectral parameter may be written as:

$${Δ}_{lsf}^{i} = \frac{{d}_{k , lsf}}{2 ( \vert k - length \vert + 1 )} \qquad i = 1 , 2 , ⋯ , M$$

where M is the order of linear prediction for the spectral parameter.

The floating center C_{G,k} of the reconstructed energy gain parameter in the reconstructed noise parameter of the current frame may be written as:

C_{G,k}=G_{ref}+2Δ_{G}

The floating center C_{lsf,k}ⁱ of the reconstructed spectral parameter in the reconstructed noise parameter of the current frame may be written as:

C_{lsf,k}ⁱ=lsf_{ref}+2Δ_{lsf}ⁱ

The reconstructed energy gain parameter Gₖ in the reconstructed noise parameter of the current frame may be written as:

Gₖ=rand(C_{G,k}−|Δ_{G}|,C_{G,k}+|Δ_{G}|)

The reconstructed spectral parameter lsfₖⁱ in the reconstructed noise parameter of the current frame may be written as:

lsfₖⁱ=rand(C_{lsf,k}ⁱ−|Δ_{lsf}ⁱ|,C_{lsf,k}ⁱ+|Δ_{lsf}ⁱ|)

where function rand(a,b) means taking a random value uniformly distributed in the interval [a, b].

When a new SID frame is received, the associated variables may be updated as follows:

length=k−1;

G_{ref}=Gₖ₋₁;

lsf_{ref}=lsfₖ₋₁ⁱ; and

finally k=1.

When a NO_DATA frame is received, the initial value of the reconstructed parameter is updated so that:

G_{ref}=Gₖ; and

lsf_{ref}=lsfₖ

The initial value of the reconstructed parameter is updated, and then k=k+1.

The reconstruction of the noise parameter of the frame continues until a new SID frame is received.

In step 404, the reconstructed noise parameter is employed to generate noise.

A white noise excitation signal e(n) is generated with a random sequence.

The reconstructed spectral parameter lsfₖ is employed to form a synthesis filter aₖ(z).

The synthesis filter is used for synthesis filtering the generated excitation signal:

yₖ(n)=e(n)*aₖ(n)

Then, the reconstructed energy gain parameter Gₖ is used for performing a time-domain shaping on the synthesized noise yₖ(n):

$$y ( n ) = {y}_{k} ( n ) \times \frac{{G}_{k}}{\sqrt{{\sum }_{i = 0}^{N - 1} {y}_{k}^{2} ( n )}}$$

where N is the length of frame in which comfortable noise may be recovered at the decoder.

In this embodiment, step 404 uses the method for noise generation with the reconstructed noise parameter, that is, the first method for noise generation with the excitation signal and the reconstructed noise parameter.

In this embodiment, there is no limit to the protocol standards used at the encoder. No matter whether the encoder transmits SID frames at fixed intervals or transmits SID frames at adaptive intervals, a smooth noise parameter may be reconstructed, including the energy gain parameter, the spectral parameter, etc. Thus, natural comfortable noise may be generated.

When a transition occurs from the speech segment to the noise segment, the noise parameter is reconstructed by taking the noise parameter of the newly received SID frame as the initial value and referring to the newly received noise parameter. When a change occurs from the speech segment to the noise segment, the transmitted SID frame is very close to the speech segment. Thus, the noise parameter of the newly received SID frame may be used directly as the initial value. Therefore, the transition from the speech segment to the noise segment will be more natural. Every time a new SID frame is received, the reconstructed noise parameter of the previous frame will be taken as the initial value. The reconstruction of the noise parameter also refers to the newly received noise parameter. Thus, the transition of the generated noise will be more natural and the user may have a better listening experience. Meanwhile, by referring to the influence of the actual noise parameter, the user may discern the approximate speech environment. Further, the noise parameter increment which has a further influence on the random value range of the reconstruct noise parameter is obtained according to the difference between the latest SID frame and the previous SID frame, and the difference between the initial value of the reconstructed parameter and the noise parameter reconstructed for the frame previous to the latest SID frame. The value range influenced by the noise parameter increment changes smoothly relative to the previous frame. The reconstructed noise parameter having a random value within this range will be influenced accordingly so that the changing curve of the reconstructed noise parameter is smooth. Therefore, the transition of the generated noise between frames will be more natural, and a better listening experience may be brought to the user.

The apparatus for noise generation as provided in an embodiment of the invention is generally located in the decoder. The noise parameter having a random change and a smooth curve may be reconstructed through the use of the noise parameters of a small number of SID frames, and noise comfortable to the user experience may be recovered.

Those skilled in the art may understand that all or some of the steps in the above method according to the embodiments of the invention may be implemented by a program to instruct the associated hardware. The program may be stored in a computer readable media. When the program is executed, the above mentioned storage media may be a Read Only Memory (ROM), a magnetic disk, an optic disc, etc.

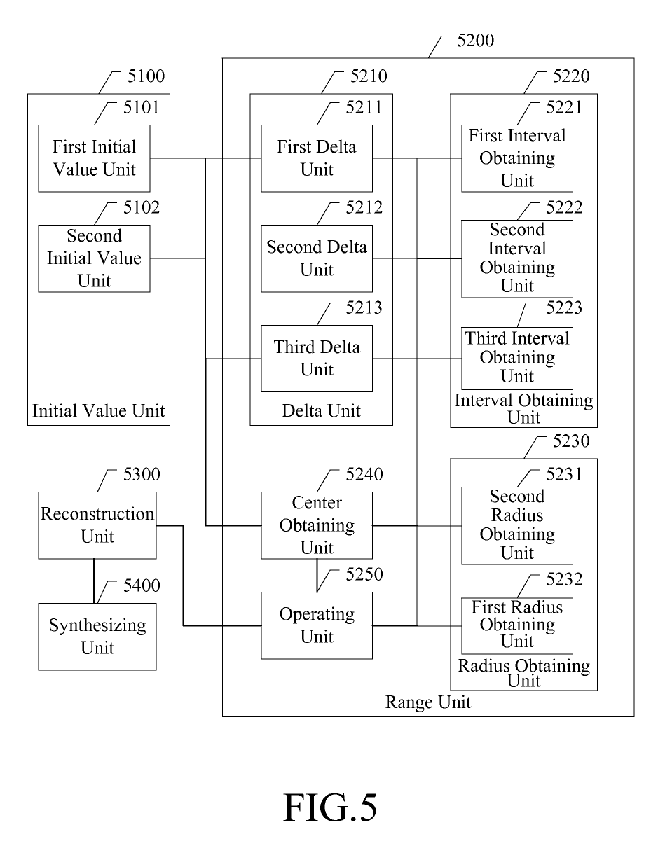

The apparatus for noise generation as provided in an embodiment of the invention may have a configuration of FIG. 5 and include the following components.

an initial value unit 5100, configured to obtain an initial value of a reconstructed parameter according to a noise parameter obtained in advance;

a range unit 5200, configured to obtain a random value range based on the initial value of the reconstructed parameter;

a reconstruction unit 5300, configured to take a value in the random value range randomly as a reconstructed noise parameter; and

a synthesizing unit 5400, configured to synthesize noise by using the reconstructed noise parameter.

The decoder uses a random sequence generator to synthesize an excitation signal. When noise is reconstructed, the excitation signal is equivalent to what an SID frame lacks as compared to an ordinary speech frame, for example, parameters associated with the fixed codebook and the adaptive codebook, etc. Based on the commonness of noise, the decoder uses a random sequence generator to synthesize an excitation signal for noise reconstruction.

The synthesizing unit 5400 may use two methods for noise generation with the excitation signal and the reconstructed noise parameter.

In the first method, the synthesizing unit 5400 converts the spectral parameter in the reconstructed noise parameter to synthesis filter coefficients, synthesis filters the excitation signal, and obtains a noise signal. Then, a time-domain shaping is performed on the synthesized noise signal by using the energy gain parameter in the reconstructed noise parameter. A post processing is performed, and the final reconstructed noise may be output.

In the second method, the synthesizing unit 5400 uses the energy gain parameter in the reconstructed noise parameter and the random sequence generator to synthesize an excitation signal. Then, the spectral parameter in the reconstructed noise parameter is converted to the synthesis filter coefficients. A synthesis filter is applied to the excitation signal to obtain the noise signal.

The initial value unit 5100 may include a first initial value unit 5101, and optionally a second initial value unit 5102.

The first initial value unit 5101 is configured to: upon receiving a first SID frame, take the average value or weighted average value of the noise parameters for a predetermined number of frames previous to the SID frame as the initial value of the reconstructed parameter.

The second initial value unit 5102 is configured to: upon receiving any SID frame subsequent to receiving the first SID frame, take the reconstructed noise parameter for a frame previous to the newly received SID frame as the initial value of the reconstructed parameter; or when reconstructing the noise parameter for a NO_DATA frame, take the reconstructed noise parameter for a frame previous to the NO_DATA frame as the initial value of the reconstructed parameter.

The range unit 5200 may include:

an increment unit 5210, configured to obtain a noise parameter increment based on a noise parameter obtained from an SID frame;

an interval obtaining unit 5220, configured to obtain a predicted interval length;

a radius obtaining unit 5230, configured to obtain a floating radius based on the predicted interval length and the noise parameter increment;

a center obtaining unit, configured to obtain a floating center based on the initial value of the reconstructed parameter and the floating radius; and

an operating unit 5240, configured to determine the random value range by taking the floating center as the center of the random value range and taking the floating radius as the radius of the random value range.

The increment unit 5210 may include a first increment unit 5211, a second increment unit 5212, or a third increment unit 5213.

The first increment unit 5211 is configured to take the difference between a noise parameter obtained from a newly obtained SID frame and the initial value of the reconstructed parameter as the noise parameter increment.

The second increment unit 5212 is configured to take the difference between a noise parameter obtained from a newly obtained SID frame and a noise parameter obtained from a previous SID frame as the noise parameter increment.

The third increment unit 5213 is configured to take the difference between the difference between a noise parameter obtained from a newly obtained SID frame and a noise parameter obtained from a previous SID frame and the difference between the initial value of the reconstructed parameter and a reconstructed noise parameter for the frame previous to the newly obtained SID frame, as the noise parameter increment.

The radius obtaining unit 5230 may include a first radius obtaining unit 5231 or a second radius obtaining unit 5232.

The first radius obtaining unit 5231 is configured to obtain the floating radius by dividing the noise parameter increment by twice the predicted interval length.

The second radius obtaining unit 5232 is configured to obtain the floating radius based on the noise parameter increment, the predicted interval length, and the distance between the current frame and the newly received SID frame.

The interval obtaining unit 5220 may include a first interval obtaining unit 5221 or a second interval obtaining unit 5222, and optionally a third interval obtaining unit 5223.

The first interval obtaining unit 5221 is configured to take a predetermined value as the length of the interval upon receiving a first SID frame.

The second interval obtaining unit 5222 is configured to upon receiving a first SID frame, take a Transmission Speech Insertion Descriptor frame interval set by the system as the length of the interval.

The third interval obtaining unit 5223 is configured to when receiving any SID frame subsequent to receiving the first SID frame or reconstructing the noise parameter for a NO_DATA frame, take the length of the interval between a newly received SID frame and a previously received SID frame as the predicted interval length.

The method of operating the apparatus for noise generation as provided in the embodiment of the invention is substantially similar to the above method for noise generation as provided in the embodiments of the invention, and thus no repetition is made here.

In this embodiment, there is no limit to the protocol standards used in the encoder. The technical solution of the invention is operable whether the encoder transmits SID frames at fixed intervals or transmits SID frames at adaptive intervals. Moreover, each time a new SID frame is received, noise parameter reconstruction will refer to the reconstructed noise parameter of the previous frame and the newly received noise parameter. Thus, the transition of the generated noise is more natural and a better listening experience may be brought to the user. Moreover, the influence of the actual noise parameter is referred to so that the user may discern the approximate speech environment. Further, when a NO_DATA frame is processed, a noise parameter having a slight change relative to the previous frame is reconstructed for the NO_DATA frame based on the distance between the NO_DATA frame and the latest SID frame, the changing direction of the noise parameter of the latest SID frame, and the difference between the noise parameter of the latest SID frame and the initial value of the reconstructed parameter. In this way, the changing curve of the reconstructed noise parameter is smooth. Accordingly, the transition of the generated noise is more natural between frames, and a better listening experience may be brought to the user.

Detailed descriptions have been made above to the apparatus and method for noise generation as provided in the invention. Some specific exemplary embodiments are taken to explain the principles and implementations of the invention, which are merely used for facilitating the understanding of the method and the basic idea of the invention. To those skilled in the art, various changes are possible without departing from the scope of the invention. Therefore, the above description shall not be construed to limit the scope of the invention.

What is claimed is:

1. A method for noise generation, comprising:
determining an initial value of a reconstructed spectral parameter;
determining a spectral parameter increment based on a spectral parameter obtained from an SID frame;
determining a predicted interval length, and determining a floating radius based on the predicted interval length and the spectral parameter increment;
determining a floating center based on the initial value of the reconstructed spectral parameter and the floating radius; and
determining the random value range by taking the floating center as the center of the random value range and taking the floating radius as the radius of the random value range;
taking a value in the random value range randomly as a reconstructed spectral parameter; and
generating noise by using the reconstructed spectral parameter.

2. The method for noise generation according to claim 1, wherein the process of determining the initial value of the reconstructed spectral parameter comprises:
upon receiving a first Silence Insertion Descriptor (SID) frame, taking the average value or weighted average value of the spectral parameters for a predetermined number of frames previous to the first SID frame as the initial value of the reconstructed spectral parameter.

3. The method for noise generation according to claim 2, wherein the process of determining the initial value of the reconstructed spectral parameter further comprises:
upon receiving any SID frame subsequent to the receiving of the first SID frame, taking the reconstructed spectral parameter for a frame previous to the newly received SID frame as the initial value of the reconstructed spectral parameter; or
when a noise parameter is reconstructed for a NO_DATA frame, taking the reconstructed spectral parameter for a frame previous to the NO_DATA frame as the initial value of the reconstructed spectral parameter.

4. The method for noise generation according to claim 1, wherein the process of determining the floating center based on the initial value of the reconstructed spectral parameter and the floating radius comprises:
taking the sum of the initial value of the reconstructed parameter and twice the floating radius as the floating center.

5. The method for noise generation according to claim 1, wherein the process of determining the spectral parameter increment based on the spectral parameter obtained from the SID frame comprises:
taking the difference between a spectral parameter obtained from a newly obtained SID frame and the initial value of the reconstructed parameter as the spectral parameter increment; or
taking the difference between a spectral parameter obtained from a newly obtained SID frame and a spectral parameter obtained from a previous SID frame as the spectral parameter increment; or
taking the difference between a spectral parameter obtained from a newly obtained SID frame and a spectral parameter obtained from a previous SID frame and the difference between the initial value of the reconstructed spectral parameter and the reconstructed spectral parameter for a frame previous to the newly obtained SID frame, as the spectral parameter increment.

6. The method for noise generation according to claim 1, wherein the process of determining the floating radius based on the predicted interval length and the spectral parameter increment comprises:
taking
$$\frac{dP}{2 * length}$$
as the floating radius; or
taking
$$\frac{dP}{2 ( \vert k - length \vert + 1 )}$$
as the floating radius;
where dP is the spectral parameter increment, length is the predicted interval length, and k is the distance between the current frame and the newly received SID frame.

7. The method for noise generation according to claim 1, wherein the process of determining the predicted interval length comprises:
upon receiving a first SID frame, taking a predetermined value as the predicted interval length; or
taking a Silence Insertion Descriptor frame interval set by the system as the predicted interval length.

8. The method for noise generation according to claim 7, wherein the process of determining the predicted interval length further comprises:
when receiving any SID frame subsequent to receiving the first SID frame or reconstructing the noise parameter for a NO_DATA frame, taking the length of the interval between the newly received SID frame and a previously received SID frame as the predicted interval length.

9. A computer readable storage medium, comprising computer program codes which when executed by a computer processor cause the compute processor to execute the steps of:
determining an initial value of a reconstructed spectral parameter;
determining a spectral parameter increment based on a spectral parameter obtained from an SID frame;
determining a predicted interval length, and determining a floating radius based on the predicted interval length and the spectral parameter increment;
determining a floating center based on the initial value of the reconstructed spectral parameter and the floating radius; and
determining the random value range by taking the floating center as the center of the random value range and taking the floating radius as the radius of the random value range;
taking a value in the random value range randomly as a reconstructed spectral parameter; and
generating noise by using the reconstructed spectral parameter.
